(19) United States
(12) Patent Application Publication
(10) Pub. No.: US 2026/0075810 A1
(43) Pub. Date: Mar. 12, 2026

(54) SEMICONDUCTOR DEVICE INCLUDING LEAKAGE PREVENTION LAYER AND METHOD OF MANUFACTURING THE SAME

(71) Applicant: NANYA TECHNOLOGY CORPORATION, NEW TAIPEI CITY (TW)

(72) Inventor: TSENG-FU LU, NEW TAIPEI CITY (TW)

(21) Appl. No.: 18/916,419

(22) Filed: Oct. 15, 2024

Related U.S. Application Data
(62) Division of application No. 18/829,688, filed on Sep. 10, 2024.

(51) Int. Cl. H10B 12/00; H01L 29/06

(52) U.S. Cl. CPC H10B 12/488; H10B 12/315; H10B 12/482; H10D 62/102

(57) ABSTRACT

A semiconductor device and method for manufacturing the same are provided. The semiconductor device includes a substrate, a bit line, and a word line. The substrate includes an active region. The word line is embedded within the substrate and extends along a first direction. The bit line is disposed over the substrate and extends along a second direction different from the first direction. The active region includes a first semiconductor layer with a first dopant concentration and a second semiconductor layer with a second dopant concentration less than the first dopant concentration.

### CROSS-REFERENCE TO RELATED APPLICATION

This application is a divisional application of U.S. Non-Provisional application Ser. No. 18/829,688 filed Sep. 10, 2024, which is incorporated herein by reference in its entirety.

### TECHNICAL FIELD

The present disclosure relates to a semiconductor device and method for manufacturing the same, and more particularly, to a semiconductor device including a leakage prevention layer and method for manufacturing the same.

### DISCUSSION OF THE BACKGROUND

With the rapid growth of the electronics industry, the development of integrated circuits (ICs) has achieved high performance and miniaturization. Technological advances in IC materials and design have produced generations of ICs where each generation has smaller and more complex circuits than the previous generation.

A Dynamic Random Access Memory (DRAM) device is a type of random access memory that stores each bit of data in a separate capacitor within an integrated circuit. Typically, a DRAM is arranged in a square array of one capacitor and transistor per cell. A vertical transistor has been developed for the 4F² DRAM cell, where F stands for the photolithographic minimum feature width or critical dimension (CD). However, recently, DRAM manufacturers face the tremendous challenge of shrinking the memory cell area as the word line spacing continues to shrink. For example, the leakage between a landing pad and a bit line has become a critical issue, which reduces the performance of a semiconductor device.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a semiconductor device. The semiconductor device includes a substrate, a bit line, and a word line. The substrate includes an active region. The word line is embedded within the substrate and extends along a first direction. The bit line is disposed over the substrate and extends along a second direction different from the first direction. The active region includes a first semiconductor layer with a first dopant concentration and a second semiconductor layer with a second dopant concentration less than the first dopant concentration.

Another aspect of the present disclosure provides a semiconductor device. The semiconductor device includes a substrate, a bit line, and a word line. The word line is embedded within the substrate and extends along a first direction. The bit line is disposed over the substrate and extends along a second direction different from the first direction. The word line includes a first conductive layer and a junction-modifying structure disposed over the first conductive layer and in contact with the active region.

Another aspect of the present disclosure provides a method of manufacturing a semiconductor device. The method includes: providing a substrate having an active region; forming a word line within the substrate, wherein the word line extends along a first direction; and forming a bit line over the substrate, wherein the bit line extends along a second direction different from the first direction, wherein forming the active region comprises: forming a first semiconductor layer with a first dopant concentration; and forming a second semiconductor layer with a second dopant concentration less than the first dopant concentration.

The embodiments of the present disclosure illustrate a semiconductor device. In some embodiments, the active region of the semiconductor device may include a first semiconductor layer and a second semiconductor layer over the first semiconductor layer. The dopant concentration of the second semiconductor layer is less than that of the first semiconductor layer. The second semiconductor layer may include epitaxial silicon. The second semiconductor layer may generate a relatively small electrical field in comparison with that generated by the first semiconductor layer. Thus, gate induced drain leakage (GIDL) current may be reduced. In some embodiments, the word line of the semiconductor device may include a junction-modifying structure sandwiched by a first conductive layer and a second conductive layer. The work function of the junction-modifying structure is smaller than that of the first conductive layer and smaller than that of the second conductive layer. Thus, the GIDL may be reduced. The resistance of the word line may be reduced. The read/write performance may be enhanced.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1A is a top view of a semiconductor device, in accordance with some embodiments of the present disclosure.

FIG. 1B is a partial cross-sectional view along line A-A′ of the semiconductor device as shown in FIG. 1A, in accordance with some embodiments of the present disclosure.

FIG. 1C is a cross-sectional view of a capacitor component as shown in FIG. 1A, in accordance with some embodiments of the present disclosure.

FIG. 2 is a flowchart illustrating a method of manufacturing a semiconductor device, in accordance with some embodiments of the present disclosure.

FIG. 3A illustrates one or more stages of an exemplary method for manufacturing a semiconductor device according to some embodiments of the present disclosure.

FIG. 3B illustrates one or more stages of an exemplary method for manufacturing a semiconductor device according to some embodiments of the present disclosure.

FIG. 3C illustrates one or more stages of an exemplary method for manufacturing a semiconductor device according to some embodiments of the present disclosure.

FIG. 3D illustrates one or more stages of an exemplary method for manufacturing a semiconductor device according to some embodiments of the present disclosure.

FIG. 3E illustrates one or more stages of an exemplary method for manufacturing a semiconductor device according to some embodiments of the present disclosure.

FIG. 3F illustrates one or more stages of an exemplary method for manufacturing a semiconductor device according to some embodiments of the present disclosure.

FIG. 3G illustrates one or more stages of an exemplary method for manufacturing a semiconductor device according to some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

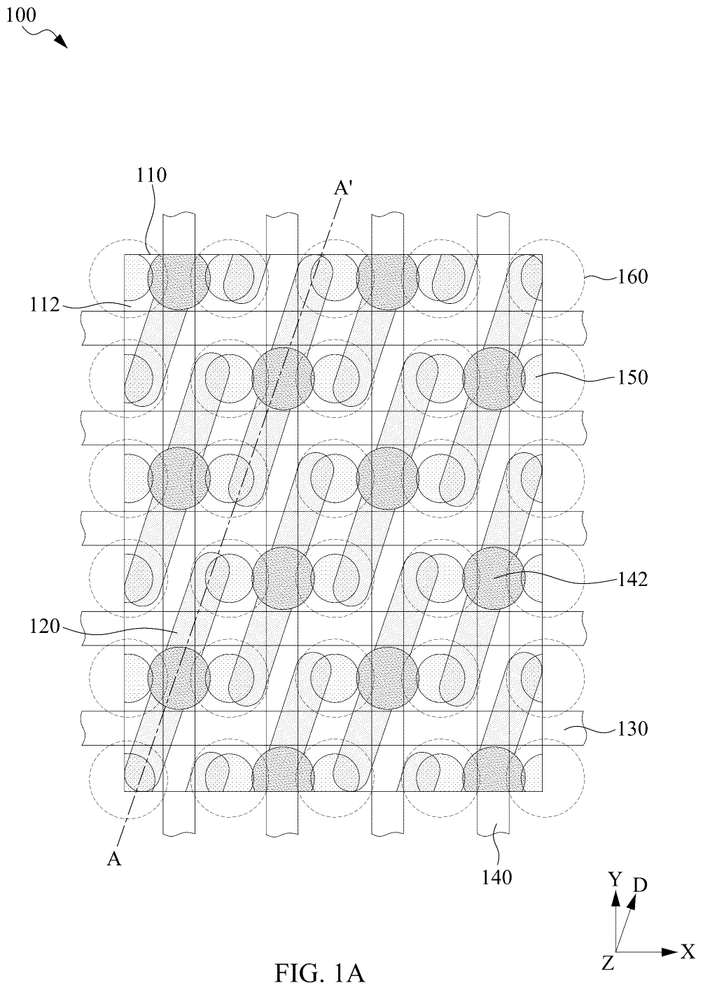

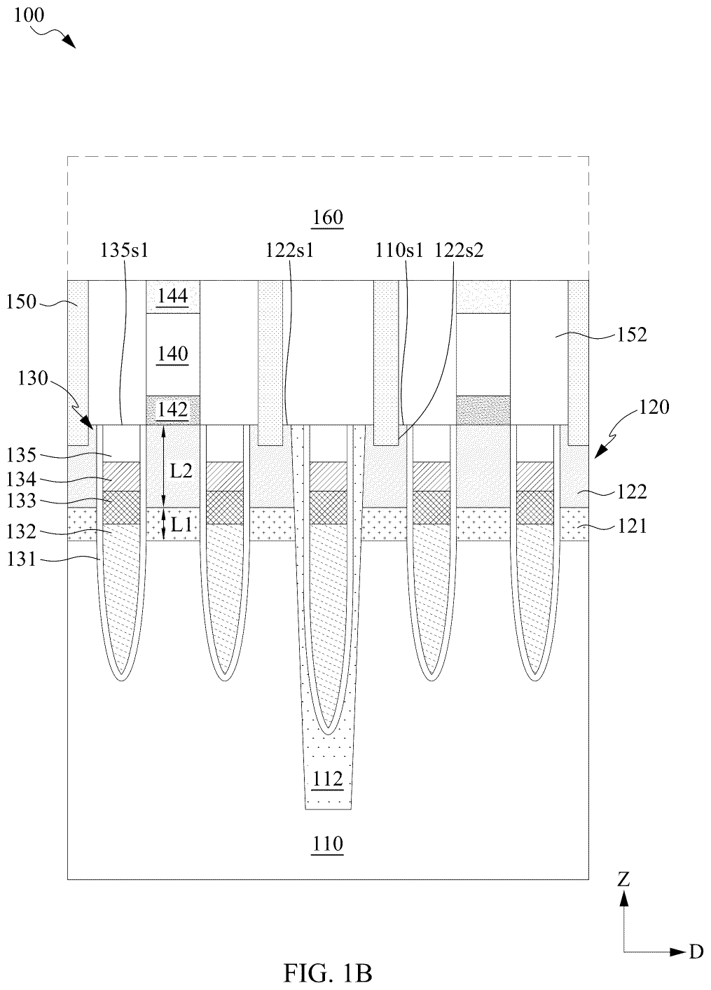

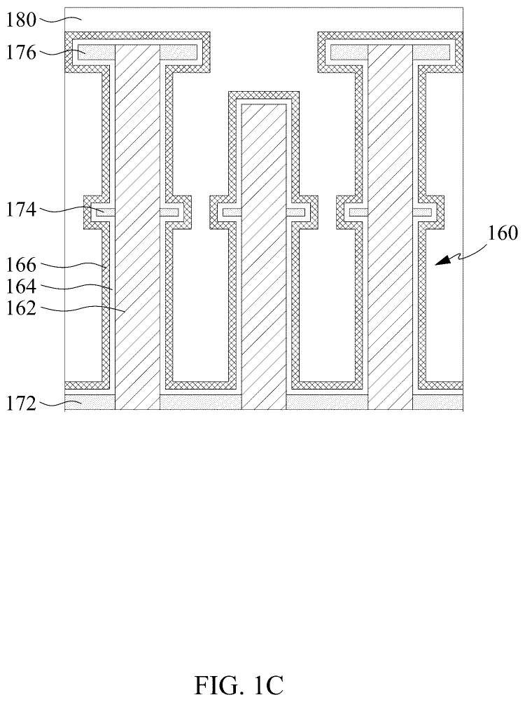

FIG. 1A is a top view of a semiconductor device 100, in accordance with some embodiments of the present disclosure. In some embodiments, the semiconductor device 100 may include a cell region in which a memory device is formed. The memory device may include, for example, a dynamic random access memory (DRAM) device, a one-time programming (OTP) memory device, a static random access memory (SRAM) device, or other suitable memory devices. In some embodiments, the DRAM may include, for example, a transistor, a capacitor, and other components. During a read operation, a word line may be asserted, turning on the transistor. The enabled transistor allows the voltage across the capacitor to be read by a sense amplifier through a bit line. During a write operation, the data to be written may be provided on the bit line when the word line is asserted.

The semiconductor device 100 may include a substrate 110, active regions 120, word lines 130, bit lines 140, capacitor contacts 150, and capacitor structures 160.

The active region 120 may be defined within the substrate 110. The active region 120 may be spaced apart from each other by isolation structures 112. Each of the active regions 120 may include an elliptical-shaped profile, an oval-shaped profile, a circular-shaped profile, or other suitable profiles. The long axis of the active region 120 may extend along the D direction, which may be slanted with respect to the X direction and the Y direction.

In some embodiments, each of the word lines 130 may extend along the X direction. The word line 130 may extend across the active regions 120.

In some embodiments, each of the bit lines 140 may extend along the Y direction. The bit line 140 may extend across the active regions 120 and the word lines 130.

In some embodiments, each of the bit line contacts 142 may be connected to the bit line 140. In some embodiments, the bit line contact 142 may overlap the bit line 140 along the Z direction. In some embodiments, the bit line contact 142 may overlap the active region 120 along the Z direction.

Each of the capacitor contacts 150 may be surrounded by the word lines 130 and the bit lines 140. The capacitor contact 150 may partially overlap the active region 120 along the Z direction.

The capacitor structure 160 may be disposed on or over the capacitor contact 150. The capacitor structure 160 may overlap the capacitor contact 150 along the Z direction.

FIG. 1B is a partial cross-sectional view along line A-A′ of the semiconductor device 100 as shown in FIG. 1A, in accordance with some embodiments of the present disclosure.

The substrate 110 may be a semiconductor substrate, such as a bulk semiconductor, a semiconductor-on-insulator (SOI) substrate, or the like. The substrate 110 may include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GaInAs, GaInP, and GaInAsP; any other suitable materials; or a combination thereof. In some embodiments, the alloy semiconductor substrate may be a SiGe alloy with a gradient Ge feature in which the Si and Ge composition changes from one ratio at one location to another ratio at another location of the gradient SiGe feature. In another embodiment, the SiGe alloy is formed over a silicon substrate. In some embodiments, a SiGe alloy may be mechanically strained by another material in contact with the SiGe alloy. In some embodiments, the substrate 110 may have a multilayered structure, or the substrate 110 may include a multilayered compound semiconductor structure. In some embodiments, the substrate 110 may have a first conductive type (e.g., P-type).

In some embodiments, the isolation structure 112 may be embedded in the substrate 110. The isolation structure 112 may be recessed from a surface 110s1 (or an upper surface) of the substrate 110. In some embodiments, the isolation structure 112 may include, for example, silicon oxide (SiO₂), silicon nitride (Si₃N₄), silicon oxynitride (N₂OSi₂), silicon nitride oxide (N₂OSi₂), or other suitable materials.

In some embodiments, a portion of the substrate 110 may be removed to form trenches, and a dielectric material(s) is filled into the trenches to form the isolation structure 112. In some embodiments, the isolation structure 112 may include a shallow trench isolation (STI).

In some embodiments, the active region 120 may include a semiconductor layer 121 and a semiconductor layer 122. The semiconductor layer 121 may be disposed within the substrate 110. In some embodiments, the semiconductor layer 121 may be spaced apart from the surface 110s1 of the substrate 110. In some embodiments, the semiconductor layer 121 may have a second conductive type (e.g., N-type). In some embodiments, the dopant concentration of the semiconductor layer 121 may range between about 10¹⁴ cm⁻³ and about 10¹⁵ cm⁻³.

The semiconductor layer 122 may be disposed on or over the semiconductor layer 121. In some embodiments, the semiconductor layer 122 is closer to the surface 110s1 of the substrate 110 than the semiconductor layer 121 is. In some embodiments, the dopant concentration of the semiconductor layer 122 may be less than that of the semiconductor layer 121. In some embodiments, the dopant concentration of the semiconductor layer 122 may be less than 10¹⁴ cm⁻³. In some embodiments, the dopant concentration of the semiconductor layer 122 may be substantially equal to zero.

In some embodiments, the semiconductor layer 122 may be configured to reduce the GIDL current. In some embodiments, the semiconductor layer 122 generates or induces a relatively small electric field for the GIDL current compared to the semiconductor layer 121.

In some embodiments, the semiconductor layer 122 may include a group 14 material(s), such as silicon, germanium, a combination thereof, or other suitable materials. In some embodiments, the semiconductor layer 122 may include an epitaxial structure. For example, the semiconductor layer 122 may include an epitaxial silicon, epitaxial germanium, epitaxial silicon-germanium, or other suitable materials.

The semiconductor layer 121 may have a length L1 (or vertical length) along the Z direction. The semiconductor layer 122 may have a length L2 (or vertical length) along the Z direction. In some embodiments, the length L2 of the semiconductor layer 122 may be greater than the length L1 of the semiconductor layer 121, thereby optimizing the electric field.

The word line 130 (or gate structure) may be embedded within the 100. The word line 130 may be embedded within the isolation structure 112. In some embodiments, the word line 130 may penetrate the substrate 110. In some embodiments, the word line 130 may penetrate the semiconductor layer 121. In some embodiments, the word line 130 may penetrate the semiconductor layer 122. In some embodiments, the word line 130 may include an insulating film 131, a conductive layer 132, a junction-modifying structure 133, and a conductive layer 134.

The insulating film 131 (or gate dielectric) may be disposed within the substrate 110. The insulating film 131 may be embedded within the isolation structure 112. In some embodiments, the insulating film 131 may penetrate the substrate 110. In some embodiments, the insulating film 131 may penetrate the semiconductor layer 121. In some embodiments, the insulating film 131 may penetrate the semiconductor layer 122. The insulating film 131 may separate the conductive layer 132 from the substrate 110. The insulating film 131 may separate the conductive layer 132 from the active region 120. The insulating film 131 may separate the junction-modifying structure 133 from the substrate 110. The insulating film 131 may separate the junction-modifying structure 133 from the active region 120. The insulating film 131 may separate the conductive layer 134 from the substrate 110. The insulating film 131 may separate the conductive layer 134 from the active region 120.

The insulating film 131 may include, for example, silicon oxide (SiO₂), a high-k material, or a combination thereof. Examples of the high-k material include a dielectric material having a dielectric constant exceeding that of silicon dioxide (SiO₂), or a dielectric material having a dielectric constant higher than about 3.9. In some embodiments, the high-k material include may include hafnium oxide (HfO₂), silicon doped hafnium oxide (HSO), lanthanum oxide (La₂O₃), lanthanum aluminum oxide (LaAlO₃), zirconium orthosilicate (ZrSiO₄), aluminum oxide (Al₂O₃) or other suitable materials.

The conductive layer 132 may be embedded within the 100. The conductive layer 132 may be embedded within the isolation structure 112. In some embodiments, the conductive layer 132 may penetrate the substrate 110. In some embodiments, the conductive layer 132 may penetrate the semiconductor layer 121. In some embodiments, the conductive layer 132 may penetrate the semiconductor layer 122. In some embodiments, the conductive layer 132 may include metal, metallic nitride, alloy, or other suitable materials. The conductive layer 132 may include titanium (Ti), tungsten (W), copper (Cu), ruthenium (Ru), iridium (Ir), nickel (Ni), osmium (Os), rhodium (Rh), aluminum (Al), molybdenum (Mo), cobalt (Co), silver (Ag), gold (Au), titanium nitride, tungsten nitride, or other suitable materials. In some embodiments, the conductive layer 132 may laterally overlap the semiconductor layer 121 or overlap the semiconductor layer 121 along the D direction.

The junction-modifying structure 133 may be disposed on or over the conductive layer 132. The junction-modifying structure 133 may be disposed between the conductive layer 132 and conductive layer 134. The junction-modifying structure 133 may be embedded within the isolation structure 112. In some embodiments, the junction-modifying structure 133 may penetrate the substrate 110. In some embodiments, the junction-modifying structure 133 may penetrate the semiconductor layer 121. In some embodiments, the junction-modifying structure 133 may penetrate the semiconductor layer 122. The junction-modifying structure 133 may be disposed between the conductive layer 132 and the conductive layer 134. The junction-modifying structure 133 may be configured to modify the work function of the word line 130. The junction-modifying structure 133 may be configured to reduce the GIDL current. In some embodiments, the work function of the junction-modifying structure 133 may be less than that of the conductive layer 132. In some embodiments, the work function of the junction-modifying structure 133 may be less than that of the conductive layer 134.

In some embodiments, the junction-modifying structure 133 may include a group 14 material(s). In some embodiments, the junction-modifying structure 133 may include doped polysilicon or other suitable materials, such as doped germanium, or other suitable materials. In some embodiments, the junction-modifying structure 133 may have the second conductive type. In some embodiments, the dopant concentration of the junction-modifying structure 133 may be greater than that of the semiconductor layer 121. In some embodiments, the dopant concentration of the junction-modifying structure 133 may be greater than that of the semiconductor layer 122. In some embodiments, the dopant concentration of the junction-modifying structure 133 may range between about 10¹⁹ cm⁻³ and about 5×10²⁰ cm⁻³.

In some embodiments, the junction-modifying structure 133 may laterally overlap the semiconductor layer 121 or overlap the semiconductor layer 121 along the D direction. In some embodiments, the junction-modifying structure 133 may laterally overlap the semiconductor layer 122 or overlap the semiconductor layer 122 along the D direction.

The conductive layer 134 may be disposed on or over the junction-modifying structure 133. The conductive layer 134 may be embedded within the 100. The conductive layer 134 may be embedded within the isolation structure 112. In some embodiments, the conductive layer 134 may penetrate the substrate 110. In some embodiments, the conductive layer 132 may penetrate the semiconductor layer 121. In some embodiments, the conductive layer 134 may penetrate the semiconductor layer 122. In some embodiments, the conductive layer 134 may include metal, metallic nitride, alloy, or other suitable materials. The conductive layer 132 may include titanium (Ti), tungsten (W), copper (Cu), ruthenium (Ru), iridium (Ir), nickel (Ni), osmium (Os), rhodium (Rh), aluminum (Al), molybdenum (Mo), cobalt (Co), silver (Ag), gold (Au), titanium nitride, tungsten nitride, or other suitable materials. In some embodiments, the conductive layer 134 may laterally overlap the semiconductor layer 122 or overlap the semiconductor layer 122 along the D direction.

A cap layer 135 may be disposed on or over the conductive layer 134. The cap layer 135 may cover the word line 130. The cap layer 135 may be formed of an insulating material, such as silicon nitride (Si₃N₄), silicon oxynitride (N₂OSi₂), silicon nitride oxide (N₂OSi₂), or other suitable materials. In some embodiments, a surface 135s1 (e.g., upper surface) of the cap layer 135 may be substantially aligned or coplanar with a surface 122s1 (or upper surface) of the semiconductor layer 122.

In some embodiments, the bit line contact 142 may be disposed on or over the substrate 110. In some embodiments, the bit line contact 142 may be disposed on or over the active region 120. In some embodiments, the bit line contact 142 may be disposed on or over the semiconductor layer 122. In some embodiments, the bit line contact 142 may be in contact with the semiconductor layer 122. In some embodiments, the bit line contact 142 may include a conductive film, such as tungsten (W), copper (Cu), ruthenium (Ru), iridium (Ir), nickel (Ni), osmium (Os), rhodium (Rh), aluminum (Al), molybdenum (Mo), cobalt (Co), silver (Ag), gold (Au), alloys combinations thereof or any metallic material with suitable resistance and gap-fill capability. In some embodiments, the bit line contact 142 may include polysilicon. In some embodiments, the bit line contact 142 may include one or more layers.

In some embodiments, the bit line 140 may be disposed on or over the active region 120. In some embodiments, the bit line 140 may be disposed on or over the semiconductor layer 122. In some embodiments, the bit line 140 may be disposed on or over the bit line contact 142. The bit line 140 may be electrically connected to the bit line contact 142. The bit line 140 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), silver (Ag), gold (Au), alloys thereof, or combinations thereof.

The semiconductor device 100 may further include a cap layer 144. The cap layer 144 may cover the bit line 140. The cap layer 144 may be disposed on or over the bit line 140. In some embodiments, the cap layer 144 may include, for example, silicon oxide (SiO₂), silicon nitride (Si₃N₄), silicon oxynitride (N₂OSi₂), silicon nitride oxide (N₂OSi₂), or other suitable materials

In some embodiments, the capacitor contact 150 may be disposed on or over the substrate 110. In some embodiments, the capacitor contact 150 may be disposed on or over the active region 120. In some embodiments, the capacitor contact 150 may be in contact with the semiconductor layer 122. In some embodiments, a portion of the capacitor contact 150 may be embedded with the active region 120. In some embodiments, a portion of the capacitor contact 150 may be embedded with the semiconductor layer 122. In some embodiments, a portion of the capacitor contact 150 may be in contact with a surface 122s2 (or lateral surface) of the semiconductor layer 122. The capacitor contact 150 may be electrically connected to the capacitor structure 160. The capacitor contact 150 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), alloys thereof, combinations thereof or any metallic material.

The semiconductor device 100 may further include a dielectric structure 152. The dielectric structure 152 may be disposed on or over the substrate 110. The dielectric structure 152 may be disposed on or over the active region 120. The dielectric structure 152 may be disposed on or over the isolation structure 112. The bit line 140 may be embedded with the dielectric structure 152. The bit line contact 142 may be embedded with the dielectric structure 152. The cap layer 144 may be embedded with the dielectric structure 152. The capacitor contact 150 may be embedded with the dielectric structure 152. The dielectric structure 152 may include one or more layers. In some embodiments, the dielectric structure 152 may include, for example, silicon oxide (SiO₂), silicon nitride (Si₃N₄), silicon oxynitride (N₂OSi₂), silicon nitride oxide (N₂OSi₂), or other suitable materials.

Although not shown in FIG. 1B, the semiconductor device 100 may further include other features based on requirements. For example, the semiconductor device 100 may further include bit line spacers disposed on sidewalls of the bit line 140, bit line contact 142, and cap layer 144. In some embodiments, the bit line spacer may include one or more materials, such as, silicon oxide, silicon nitride, silicon oxynitride, silicon nitride oxide, a high-k material, air gap, or combinations thereof.

In some embodiments, the semiconductor device 100 may further include landing pads. In some embodiments, the landing pad may cover a top surface of the capacitor contact 150. The landing pad may electrically connect the capacitor contact 150 and the capacitor structure 160. The landing pad may penetrate a portion of the bit line spacer and the dielectric structure 152. In some embodiments, the pad 146 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), silver (Ag), gold (Au), alloys thereof, or combinations thereof.

FIG. 1C is a cross-sectional view of features (e.g., capacitor components) over the capacitor contact 150, in accordance with some embodiments of the present disclosure.

The semiconductor device 100 may further include a supporting layer 172, a supporting layer 174, and a supporting layer 176 which are located at different elevations and configured to support a capacitor structure 160.

In some embodiments, the supporting layer 172 (or a lower supporting layer) may be disposed on or over the dielectric structure 152 as shown in FIG. 1B. In some embodiments, the supporting layer 172 may be configured to support the capacitor structure 160. The supporting layer 172 may be utilized to define the patterns of the capacitor structure 160. In some embodiments, the supporting layer 172 may include silicon nitride, silicon oxide, silicon oxynitride, silicon nitride oxide, or other suitable materials.

In some embodiments, the supporting layer 174 (or a middle supporting layer) may be disposed on or over the supporting layer 172. In some embodiments, the supporting layer 174 may be spaced apart from the supporting layer 172. In some embodiments, the supporting layer 174 may be configured to support the capacitor structure 160. The supporting layer 174 may be utilized to define the patterns of the capacitor structure 160. In some embodiments, the supporting layer 174 may include silicon nitride, silicon oxide, silicon oxynitride, silicon nitride oxide, or other suitable materials.

In some embodiments, the supporting layer 176 (or an upper supporting layer) may be disposed on or over the supporting layer 174. In some embodiments, the supporting layer 176 may be spaced apart from the supporting layer 174. In some embodiments, the supporting layer 176 may be configured to support the capacitor structure 160. The supporting layer 176 may be utilized to define the patterns of the capacitor structure 160. In some embodiments, the supporting layer 176 may include silicon nitride, silicon oxide, silicon oxynitride, silicon nitride oxide, or other suitable materials.

The capacitor structure 160 may be disposed on or over the capacitor contact 150 as shown in FIG. 1B. In some embodiments, the capacitor structure 160 may be supported by and in contact with the supporting layer 172, supporting layer 174, and supporting layer 176. In some embodiments, the capacitor structure 160 may include a lower electrode 162, a capacitor dielectric 164, and an upper electrode 166.

In some embodiments, the lower electrode 162 (or first electrode) may be electrically connected to the capacitor contact 150 as shown in FIG. 1B. In some embodiments, the lower electrode 162 may be disposed within the opening defined by the supporting layer 172, supporting layer 174, and supporting layer 176. In some embodiments, the lower electrode 162 may be disposed on or in contact with the lateral surface of the supporting layer 172. In some embodiments, the lower electrode 162 may be disposed on or in contact with the lateral surface of the supporting layer 174. In some embodiments, the lower electrode 162 may be disposed on or in contact with the lateral surface of the supporting layer 176. The lower electrode 162 may include conductive material(s), conductive metal nitride (e.g., titanium nitride, tantalum nitride, tungsten nitride, or the like), metal (e.g., copper, tungsten, ruthenium, iridium, nickel, osmium, rhodium, aluminum, molybdenum, cobalt, or the like), and conductive metal oxide (e.g., iridium oxide or the like).

The capacitor dielectric 164 may be conformally disposed on the lower electrode 162. In some embodiments, the capacitor dielectric 164 may be disposed on or in contact with the upper surface of the supporting layer 172. In some embodiments, the capacitor dielectric 164 may be disposed on or in contact with the upper surfaces of the supporting layer 174 and supporting layer 176. In some embodiments, the capacitor dielectric 164 may be disposed on or in contact with the lower surfaces of the supporting layer 174 and supporting layer 176. In some embodiments, the capacitor dielectric 164 may be disposed on or in contact with the lateral surfaces of the supporting layer 174 and supporting layer 176. The capacitor dielectric 164 may include silicon oxide, tungsten oxide, copper oxide, aluminum oxide, hafnium oxide, or the like.

In some embodiments, the upper electrode 166 (or second electrode) may be disposed on the capacitor dielectric 164. The upper electrode 166 may be spaced apart from the lower electrode 162 by the capacitor dielectric 164. The upper electrode 166 may include conductive material(s), conductive metal nitride (e.g., titanium nitride, tantalum nitride, tungsten nitride, or the like), metal (e.g., copper, tungsten, ruthenium, iridium, nickel, osmium, rhodium, aluminum, molybdenum, cobalt, or the like), and conductive metal oxide (e.g., iridium oxide or the like). In some embodiments, each of the supporting layer 172, supporting layer 174, and supporting layer 176 may define a ring profile, from a top view, to accommodate the capacitor structure 160.

In some embodiments, the semiconductor device 100 may further include a grounding electrode 180. In some embodiments, the grounding electrode 180 may be electrically connected to ground. In some embodiments, the grounding electrode 180 may be electrically connected to the capacitor structure 160. In some embodiments, the grounding electrode 180 may be electrically connected to and in contact with the upper electrode 166. In some embodiments, the grounding electrode 180 may include doped polysilicon or other suitable materials.

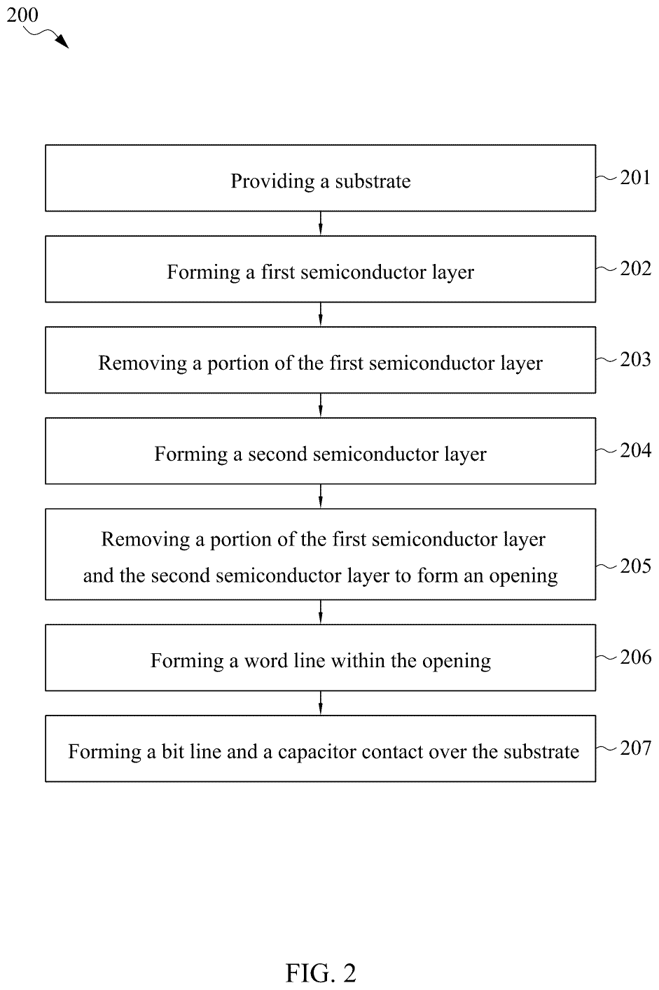

FIG. 2 is a flowchart illustrating a method 200 of manufacturing a semiconductor device, in accordance with some embodiments of the present disclosure.

The method 200 may begin with an operation 201 in which a substrate is provided. Isolation structures (e.g., STI) may be formed within the substrate.

The method 200 may continue with an operation 202 in which an implant technique is performed. A first semiconductor layer is formed.

The method 200 may continue with an operation 203 in which an etching technique is performed to remove a portion of the first semiconductor layer.

The method 200 may continue with an operation 204 in which a second semiconductor layer is formed over the first semiconductor layer. The second semiconductor layer may include an epitaxial structure, such as an epitaxial silicon, epitaxial silicon germanium, or other suitable materials. The dopant concentration of the second semiconductor layer is less than that of the first semiconductor layer. A polishing or grinding technique may be performed to planarize the upper surface of the second semiconductor layer and the isolation structure.

The method 200 may continue with an operation 205 in which a portion of the substrate, the first semiconductor layer, and second semiconductor layer are removed to form openings.

The method 200 may continue with an operation 206 in which word lines are formed within the openings. Each of the word lines may include a first conductive layer, a junction-modifying structure over the first conductive layer, and a second conductive layer over the junction-modifying structure. The work function of the junction-modifying structure may be less than that of the first conductive layer. The work function of the junction-modifying structure may be less than that of the second conductive layer. The junction-modifying structure may include a doped group 14 material, such as doped polysilicon. The dopant concentration of the junction-modifying structure may be greater than the dopant concentration of the first semiconductor layer.

The method 200 may continue with an operation 207 in which bit lines are formed on the substrate. Capacitor contacts and capacitor structures are formed over the substrate, thereby producing a semiconductor device.

The method 200 is merely an example, and is not intended to limit the present disclosure beyond what is explicitly recited in the claims. Additional operations can be provided before, during, or after each operations of the method 200, and some operations described can be replaced, eliminated, or reordered for additional embodiments of the method. In some embodiments, the method 200 can include further operations not depicted in FIG. 2. In some embodiments, the method 200 can include one or more operations depicted in FIG. 2.

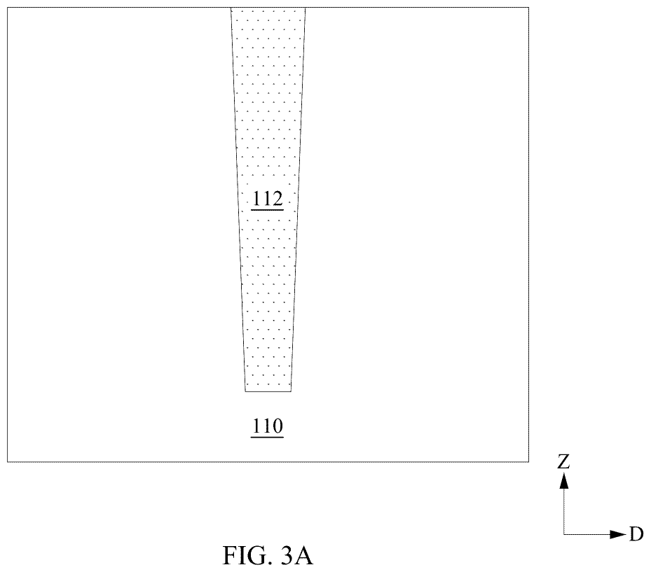

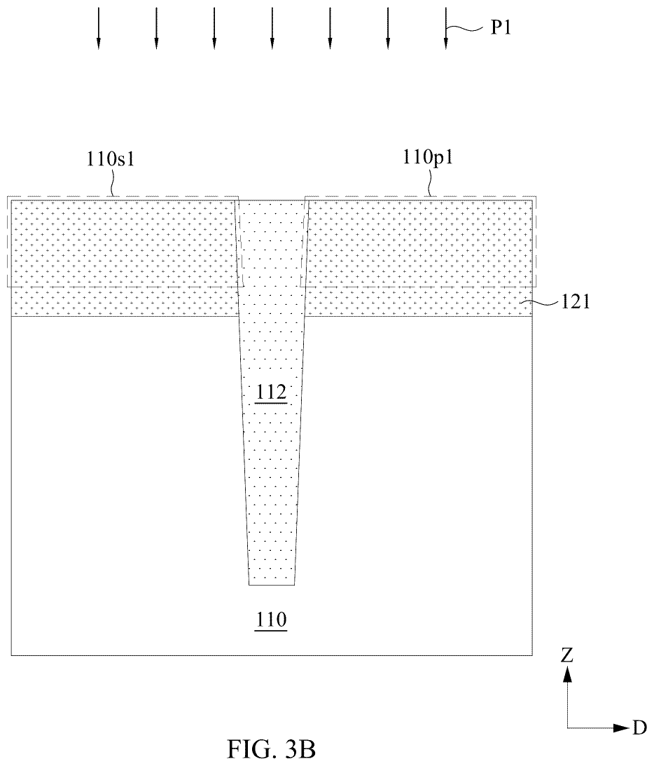

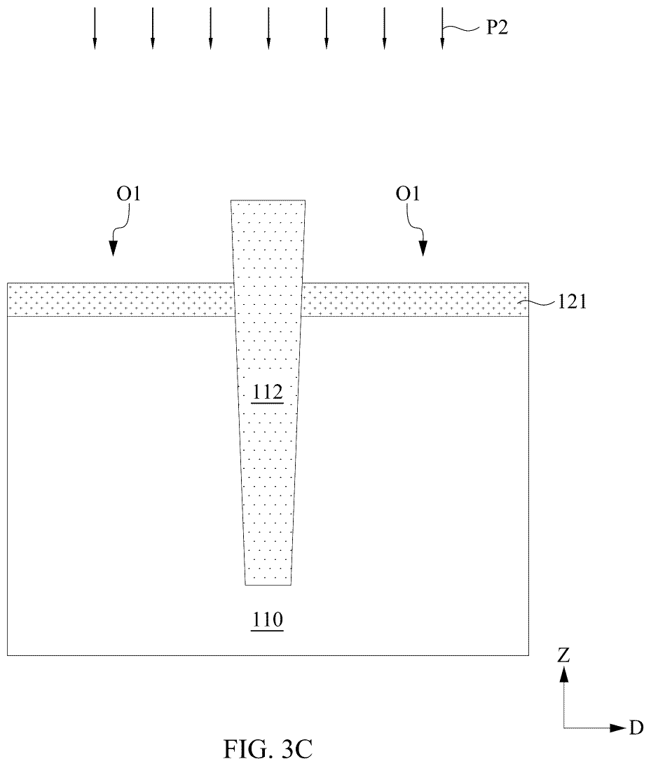

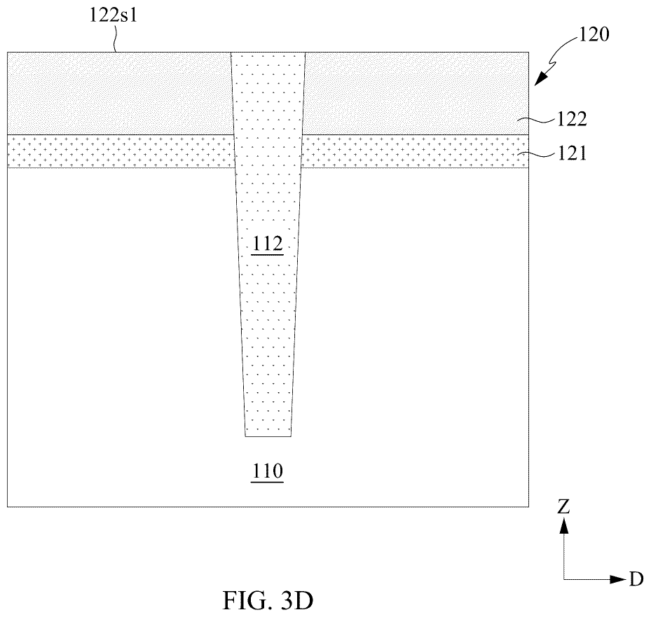

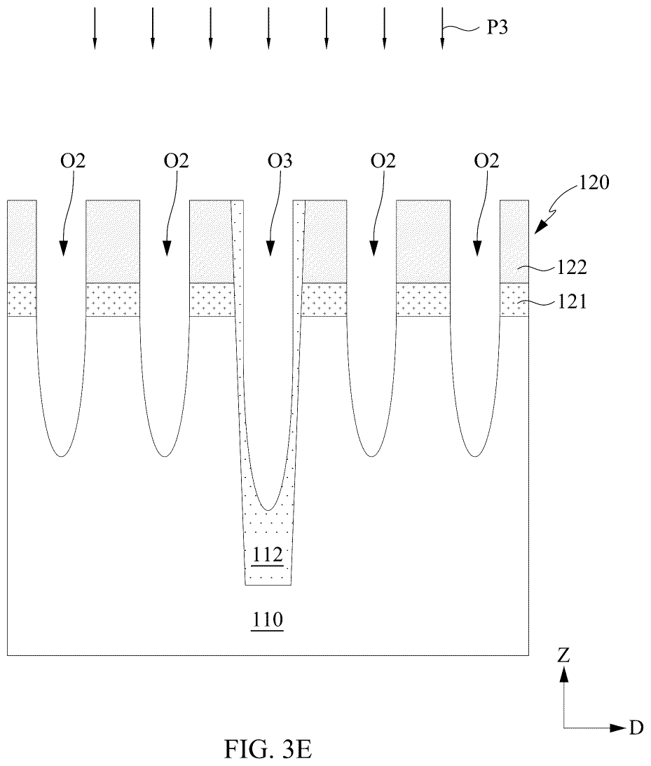

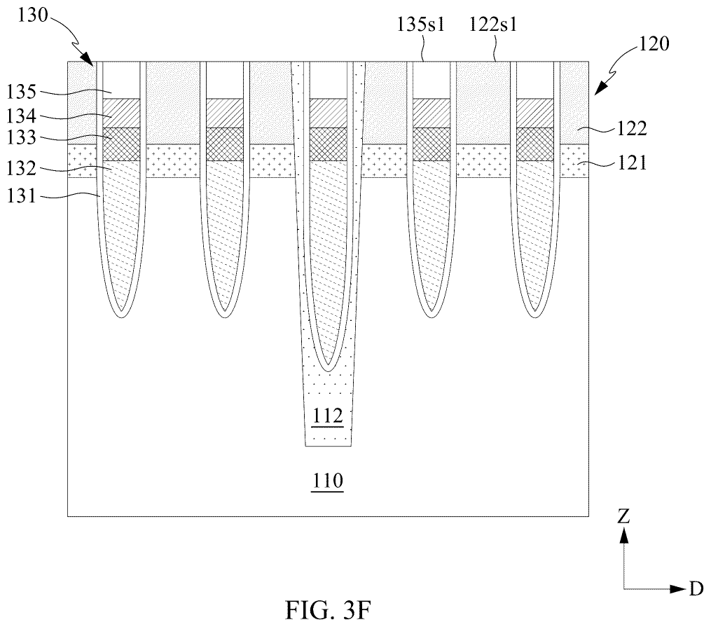

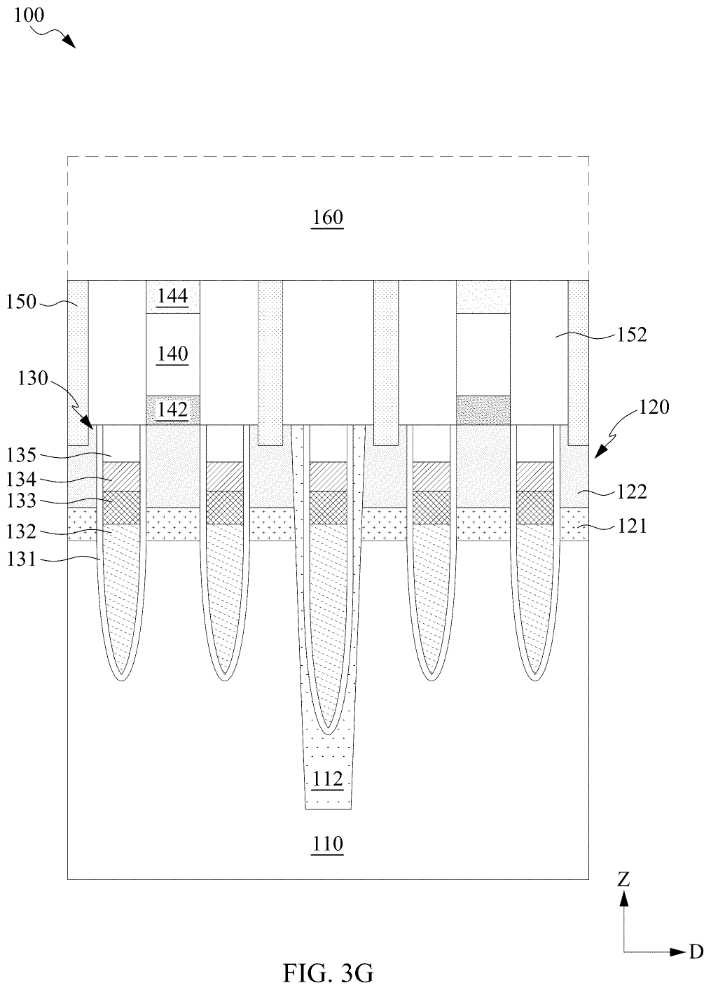

FIGS. 3A, 3B, 3C, 3D, 3E, 3F, and 3G illustrate various stages of an exemplary method for manufacturing a semiconductor device according to some embodiments of the present disclosure.

Referring to FIG. 3A, the substrate 110 may be provided. The isolation structure 112 may be formed within the substrate 110. In some embodiments, a portion of the substrate 110 may be removed to form openings (not shown), and a dielectric material(s) may be deposited to fill the openings, thereby producing the isolation structure 112. The isolation structure 112 may be formed by chemical vapor deposition (CVD), atomic layer deposition (ALD), physical vapor deposition (PVD), low-pressure chemical vapor deposition (LPCVD), flowable chemical vapor deposition (FCVD), or other suitable processes. In some embodiments, a polishing or grinding technique (e.g., a chemical mechanical polishing (CMP)) may be performed to planarize the upper surface of the substrate 110 and the upper surface of the isolation structure 112. FIG. 3A illustrate a stage corresponding to the operation 201.

Referring to FIG. 3B, an implantation technique P1 may be performed. Impurities may be doped from the surface 110s1 of the substrate 110, thereby producing the semiconductor layer 121. FIG. 3B illustrate a stage corresponding to the operation 202.

Referring to FIG. 3C, an etching technique P2 may be performed. A portion 110p1 of the substrate 110 as shown in FIG. 3B may be removed to form openings O1 (or trenches) recessed from the isolation structure 112. In some embodiments, a portion of the semiconductor layer 121 may be removed. In some embodiments, the etching technique P2 may be performed after the semiconductor layer 121 is produced. The etching technique P2 may include dry etching, wet etching, or other suitable techniques. FIG. 3C illustrate a stage corresponding to the operation 203.

Referring to FIG. 3D, a semiconductor layer 122 may be performed. In some embodiments, the semiconductor layer 122 may be formed on or over the semiconductor layer 121 to fill the openings O1. The semiconductor layer 122 may be formed, for example, metal-organic chemical vapor deposition (MOCVD), molecular beam epitaxy (MBE), liquid phase epitaxy (LPE), vapor phase epitaxy (VPE), selective epitaxial growth (SEG), the like, or combinations thereof. In some embodiments, a polishing or grinding technique (e.g., CMP) may be performed to planarize the surface 122s1 of the semiconductor layer 122 and the upper surface of the isolation structure 112. FIG. 3D illustrate a stage corresponding to the operation 204.

Referring to FIG. 3E, an etching technique P3 may be performed. In some embodiments, a portion of the semiconductor layer 121 may be removed. In some embodiments, a portion of the semiconductor layer 122 may be removed. A portion of the isolation structure 112 may be removed. Openings O2 and O3 may be formed. Openings O2 and O3 may have different depths. The etching technique P3 may include dry etching, wet etching, or other suitable techniques. In some embodiments, the etching technique P3 may be formed after the semiconductor layer 122 is produced. FIG. 3E illustrate a stage corresponding to the operation 205.

Referring to FIG. 3F, the insulating film 131, conductive layer 132, junction-modifying structure 133, conductive layer 134, and cap layer 135 may be formed within the openings. Each of the insulating film 131, conductive layer 132, junction-modifying structure 133, conductive layer 134, and cap layer 135 may be formed by CVD, PVD, ALD, PECVD, LPCVD, FCVD, or other suitable techniques. In some embodiments, a polishing or grinding technique (e.g., CMP) may be performed to planarize the surface 122s1 of the semiconductor layer 122 and the surface 135s1 of the cap layer 135. FIG. 3F illustrate a stage corresponding to the operation 206.

Referring to FIG. 3G, the bit line 140, bit line contact 142, cap layer 144, capacitor contact 150, dielectric structure 152, and the capacitor structure 160 may be formed, thereby producing the semiconductor device 100. Each of the bit line 140, bit line contact 142, cap layer 144, capacitor contact 150, dielectric structure 152, and the capacitor structure 160 may be formed by CVD, PVD, ALD, PECVD, LPCVD, FCVD, or other suitable techniques. FIG. 3G illustrate a stage corresponding to the operation 207.

One aspect of the present disclosure provides a semiconductor device. The semiconductor device includes a substrate, a bit line, and a word line. The substrate includes an active region. The word line is embedded within the substrate and extends along a first direction. The bit line is disposed over the substrate and extends along a second direction different from the first direction. The active region includes a first semiconductor layer with a first dopant concentration and a second semiconductor layer with a second dopant concentration less than the first dopant concentration.

Another aspect of the present disclosure provides a semiconductor device. The semiconductor device includes a substrate, a bit line, and a word line. The word line is embedded within the substrate and extends along a first direction. The bit line is disposed over the substrate and extends along a second direction different from the first direction. The word line includes a first conductive layer and a junction-modifying structure disposed over the first conductive layer and in contact with the active region.

Another aspect of the present disclosure provides a method of manufacturing a semiconductor device. The method includes: providing a substrate having an active region; forming a word line within the substrate, wherein the word line extends along a first direction; and forming a bit line over the substrate, wherein the bit line extends along a second direction different from the first direction, wherein forming the active region comprises: forming a first semiconductor layer with a first dopant concentration; and forming a second semiconductor layer with a second dopant concentration less than the first dopant concentration.

The embodiments of the present disclosure illustrate a semiconductor device. In some embodiments, the active region of the semiconductor device may include a first semiconductor layer and a second semiconductor layer over the first semiconductor layer. The dopant concentration of the second semiconductor layer is less than that of the first semiconductor layer. The second semiconductor layer may include epitaxial silicon. The second semiconductor layer may generate a relatively small electrical field in comparison with that generated by the first semiconductor layer. Thus, gate induced drain leakage (GIDL) current may be reduced. In some embodiments, the word line of the semiconductor device may include a junction-modifying structure sandwiched by a first conductive layer and a second conductive layer. The work function of the junction-modifying structure is smaller than that of the first conductive layer and smaller than that of the second conductive layer. Thus, the GIDL may be reduced. The resistance of the word line may be reduced. The read/write performance may be enhanced.

Although the present disclosure and its advantages have been described in detail, it should be understood that various changes, substitutions and alterations may be made herein without departing from the spirit and scope of the disclosure as defined by the appended claims. For example, many of the processes discussed above may be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor device, comprising:
a substrate comprising an active region;
a word line embedded within the substrate and extending along a first direction; and
a bit line disposed over the substrate and extending along a second direction different from the first direction,
wherein the word line comprises:
a first conductive layer; and
a junction-modifying structure disposed over the first conductive layer.

2. The semiconductor device of claim 1, wherein the junction-modifying structure comprises a doped semiconductor layer.

3. The semiconductor device of claim 2, wherein a dopant concentration of the junction-modifying structure ranges between about 10¹⁹ cm⁻³ and about 5×10²⁰ cm⁻³.

4. The semiconductor device of claim 1, wherein the word line further comprises:
a second conductive layer disposed over the junction-modifying structure.

5. The semiconductor device of claim 1, wherein the active region comprises:
a first semiconductor layer; and
a second semiconductor layer with a dopant concentration less than a dopant concentration of the first semiconductor layer.

6. The semiconductor device of claim 5, wherein the second semiconductor layer is closer to an upper surface of the substrate than the first semiconductor layer is.

7. The semiconductor device of claim 5, wherein the dopant concentration of the second semiconductor layer is substantially equal to zero.

8. The semiconductor device of claim 5, wherein a vertical length of the second semiconductor layer is greater than a vertical length of the first semiconductor layer.

9. The semiconductor device of claim 5, wherein the junction-modifying structure laterally overlaps the first semiconductor layer.

10. The semiconductor device of claim 5, wherein the junction-modifying structure laterally overlaps the second semiconductor layer.

11. The semiconductor device of claim 5, wherein a dopant concentration of the junction-modifying structure is greater than the dopant concentration of the first semiconductor layer.

12. A method of manufacturing a semiconductor device, comprising:
providing a substrate having an active region;
forming a word line within the substrate, wherein the word line extends along a first direction; and
forming a bit line over the substrate, wherein the bit line extends along a second direction different from the first direction,
wherein forming the active region comprises:
forming a first semiconductor layer with a first dopant concentration; and
forming a second semiconductor layer with a second dopant concentration less than the first dopant concentration.

13. The method of claim 12, wherein forming the first semiconductor layer and the second semiconductor layer comprises:
performing an implant technique to form the first semiconductor layer;
removing a portion of the substrate to form a trench; and
forming the second semiconductor layer within the trench.

14. The method of claim 13, further comprising:
forming isolation structures within the substrate before removing the portion of the substrate.

15. The method of claim 12, wherein the second semiconductor layer is formed prior to forming the word line.

16. The method of claim 12, wherein a dopant concentration of the second semiconductor layer is less than a dopant concentration of the first semiconductor layer.

17. The method of claim 16, wherein the dopant concentration of the second semiconductor layer is substantially equal to zero.

18. The method of claim 12, wherein forming the word line comprises:
forming an opening penetrating the first semiconductor layer and the second semiconductor layer; and
forming a first conductive layer within the opening.

19. The method of claim 18, wherein forming the word line comprises:
forming a junction-modifying structure over the first conductive layer.

20. The method of claim 19, wherein forming the word line comprises:
forming a second conductive layer over the junction-modifying structure.
